(19) United States
(12) Patent Application Publication
(10) Pub. No.: US 2012/0147350 A1
(43) Pub. Date: Jun. 14, 2012

(54) SPECTRAL PURITY FILTER, LITHOGRAPHIC APPARATUS, AND METHOD FOR MANUFACTURING A SPECTRAL PURITY FILTER

(75) Inventors: Andrei Yakunin, Eindhoven (NL); Vadim Banine, Deurne (NL); Denis Glushkov, Witten (DE)

(73) Assignee: ASML NETHERLANDS B.V, VELDHOVEN (NL)

(21) Appl. No.: 13/381,312

(22) PCT Filed: May 11, 2010
(86) PCT No.: PCT/EP10/56436

§ 371 Date: Mar. 2, 2012

Related U.S. Application Data
(60) Provisional application No. 61/222,001, filed on Jun. 30, 2009.
(60) Provisional application No. 61/237,589, filed on Aug. 27, 2009.

(51) Int. Cl. G03B 27/72; H01L 21/302; G02B 5/22

(52) U.S. Cl. 355/71; 359/353; 438/69; 257/E21.214

(57) ABSTRACT

A transmissive spectral purity filter configured to transmit extreme ultraviolet radiation includes a filter part having a plurality of apertures to transmit extreme ultraviolet radiation and to suppress transmission of a second type of radiation. The apertures may be manufactured in semiconductor material such as silicon by an anisotropic etching process. The semiconductor material is provided with a hydrogen-resistant layer, such as silicon nitride Si₃N₄, silicon dioxide SiO₂, or silicon carbide SiC.

### CROSS-REFERENCE TO RELATED APPLICATIONS

This application claims the benefit of U.S. provisional application 61/222,001 which was filed on Jun. 30, 2009, and of U.S. provisional application 61/237,589 which was filed on Aug. 27, 2009, both of which are incorporated herein in their entirety by reference

### FIELD

The present invention relates to spectral purity filters, lithographic apparatus including such spectral purity filters, and methods for manufacturing spectral purity filters.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of one or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include steppers, in which each target portion is irradiated by exposing an entire pattern onto the target portion at one time, and scanners, in which each target portion is irradiated by scanning the pattern through a radiation beam in a given direction (the “scanning” direction) while synchronously scanning the substrate parallel or anti-parallel to this direction. It is also possible to transfer the pattern from the patterning device to the substrate by imprinting the pattern onto the substrate.

A key factor limiting pattern printing is the wavelength λ of the radiation used. In order to be able to project ever smaller structures onto substrates, it has been proposed to use extreme ultraviolet (EUV) radiation which is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such EUV radiation is sometimes termed soft x-ray. Possible sources include, for example, laser-produced plasma sources, discharge plasma sources, or synchrotron radiation from electron storage rings.

EUV sources based on a tin (Sn) plasma do not only emit the desired in-band EUV radiation but also out-of-band radiation, most notably in the deep UV (DUV) range (100-400 nm). Moreover, in the case of Laser Produced Plasma (LPP) EUV sources, the infrared radiation from the laser, usually at 10.6 μm, presents a significant amount of unwanted radiation. Since the optics of the EUV lithographic system generally have substantial reflectivity at these wavelengths, the unwanted radiation propagates into the lithography tool with significant power if no measures are taken.

In a lithographic apparatus, out-of-band radiation should be minimized for several reasons. Firstly, resist is sensitive to out-of-band wavelengths, and thus the image quality may be deteriorated. Secondly, unwanted radiation, especially the 10.6 μm radiation in LPP sources, leads to unwanted heating of the mask, wafer and optics. In order to bring unwanted radiation within specified limits, spectral purity filters (SPFs) are being developed.

Spectral purity filters can be either reflective or transmissive for EUV radiation. Implementation of a reflective SPF requires modification of an existing mirror or insertion of an additional reflective element. A transmissive SPF is typically placed between the collector and the illuminator and, in principle at least, does not affect the radiation path. This may be an advantage because it results in flexibility and compatibility with other SPFs.

Grid SPFs form a class of transmissive SPFs that may be used when the unwanted radiation has a much larger wavelength than the EUV radiation, for example in the case of 10.6 μm radiation in LPP sources. Grid SPFs contain apertures with a size of the order of the wavelength to be suppressed. The suppression mechanism may vary among different types of grid SPFs as described in the prior art and detailed embodiments further in this document. Since the wavelength of EUV radiation (13.5 nm) is much smaller than the size of the apertures (typically >3 μm), EUV radiation is transmitted through the apertures without substantial diffraction.

Several prior art spectral purity filters (SPFs) rely on a grid with micron-sized apertures to suppress unwanted radiation. U.S. Patent Application Publication 2006/0146413 discloses a spectral purity filter (SPF) comprising an array of apertures with diameters up to 20 μm. Depending on the size of the apertures compared to the radiation wavelength, the SPF may suppress unwanted radiation by different mechanisms. If the aperture size is smaller than approximately half of the (unwanted) wavelength, the SPF reflects virtually all radiation of this wavelength. If the aperture size is larger, but still of the order of the wavelength, the radiation is at least partially diffracted and may be absorbed in a waveguide inside the aperture.

The approximate material parameters and specifications for these SPFs are known. However, manufacturing is not straightforward at these specifications. The most challenging specifications are: apertures of typically 4 μm in diameter; a grid thickness of typically 5-10 μm; very thin (typically <1 μm) and parallel (non-tapered) walls between the apertures to ensure maximal EUV transmission.

Silicon has emerged as a promising material for the manufacture of such grids, using the photolithographic patterning and anisotropic etching processes that are well-understood from semiconductor manufacturing. For deep apertures with a well-controlled cross-section, deep reactive ion etching (DRIE) has been found promising, although of course problems remain. U.S. Provisional patent application Ser. No. 61/193,769 filed on Dec. 22, 2008 discloses various methods for manufacture which are applicable in the present invention. The contents of that application are incorporated herein by reference.

While silicon (Si) is a promising material for the manufacture of SPFs, various mechanisms associated with contamination management in a real EUV lithography apparatus release hydrogen into the atmosphere, and hydrogen radicals (atomic H) in particular. The inventors have found that that these radicals can decompose the Si filter material and, even worse, also transfer contamination to the critical optical surfaces in the illumination system. Even the best reflective elements for EUV projection reflect a low proportion of the radiation compared with more familiar optical systems. Degradation will seriously limit the yield of a lithographic apparatus. The filter must also withstand heating effects from the various radiation wavelengths.

U.S. Pat. No. 7,031,566B2 discloses a filter for UV radiation made of ‘macroporous silicon’ in which pores have a diameter d much less than the thickness t of the wafer material. Many prior techniques for manufacturing such structures, both as spectral filters or for other applications, are reviewed. U.S. Pat. No. 7,031,566B2 proposes to apply a transparent coating of SiO₂ on the sidewalls of the pores for waveguiding of the desired wavelength. Pass-band wavelengths of 200-400 nm are mentioned, for use in analytical instruments, with pores having a diameter around l pm and depth around 50 μm. While the text of U.S. Pat. No. 7,031,566B2 refers in places to ‘extreme UV’, this is not defined and the examples given are not in the sub-20 nm range considered for the present application. Waveguide material SiO₂ is not transparent at the EUV wavelengths mentioned for next-generation photolithography.

An additional potential problem with SPFs made by silicon is that the atmosphere in EUV illumination systems, while being nominally a vacuum, in fact contains gases deliberately introduced to mitigate debris and contamination of optical surfaces, to and to create a buffer between higher vacuum areas and external ports of the apparatus. A particular gas used for this purpose is hydrogen (H₂). The conditions in the region of the EUV source lead to the production of a large number of hydrogen radicals (H atoms), which are highly reactive with the preferred silicon material of the SPF. This brings two problems: degradation of the SPF itself, and contamination of the optical system with Si transported from the SPF. Grid-like structures in particular have a relatively large exposed surface area, which may exacerbate the problem of hydrogen attack.

### SUMMARY

It is an aspect of the present invention to provide an EUV spectral purity filter which is effective and easy to manufacture, without the drawbacks associated with use of silicon components in a hydrogen radical atmosphere. The thickness of the filter part may be smaller than about 20 μm. The diameter of each aperture may be greater than about 2 μm. The diameter of each aperture may be in the range of about 2 μm to about 10 μm. The semiconductor material is preferably silicon. The apertures may have a period of in the range of about 3 μm to about 6 μm. Preferably, the filter part is substantially planar, and the plurality of apertures extend from a front surface to a rear surface of the filter part to transmit the extreme ultraviolet radiation while suppressing transmission of the second type of radiation. Each of the apertures may be defined by a textured sidewall having a roughness of at least about 80 nm. The reflective material may extend at least about 1 μm along the sidewalls of the apertures. The filter may include an integral filter holder.

According to an embodiment of the present invention, there is provided a spectral purity filter for extreme ultraviolet radiation (λ<20 nm). The filter comprises a grid-like structure fabricated in a carrier material, for example a semiconductor material such as silicon, and provided with a surface layer of hydrogen-resistant material over all or a majority of its surface area. The grid-like structure for example comprises a substantially planar filter part having a plurality of apertures, each defined by a side wall extending fully or substantially from a front surface to a rear surface of the filter part.

The hydrogen-resistant material (defined as any material significantly more resistant to radical hydrogen than the carrier material) can be applied as a coating, or formed by modification of the underlying semiconductor. Example materials are silicon nitride Si₃N₄ and/or SiN, silicon dioxide SiO₂, and silicon carbide SiC. Different materials can be used to protect different parts of the filter, according to ease of manufacture and compatibility with other materials such as reflective coatings. The protective material be selected also for optical properties such as transmission or reflectance of wanted and unwanted radiation. In other words, a special hydrogen protective material need not be added on parts where a functional material having hydrogen resistance is already to be provided, for example as a reflector or waveguide.

The spectral purity filter may be of the transmissive type comprising a filter part having a plurality of apertures extending from a front to a rear surface of the filter part to transmit the extreme ultraviolet radiation while suppressing transmission of a second type of radiation. The dimensions of each aperture in the plane of the filter part may be greater than about 2 μm, for example in the range of about 1.5 μm to about 10 μm, about 1.5 μm to about 4 μm, or about 2 μm to about 3 μm. This size is much greater than the EUV wavelengths of interest, but comparable with the wavelengths of far infrared, for example, which are to be suppressed. The hydrogen-resistant material may cover internal walls of the apertures as well as front and/or rear surfaces.

The spectral purity filter may include a filter part comprising silicon (Si) and having a thickness of about 10 μm, and a plurality of apertures in the filter part, each aperture being defined by a substantially perpendicular sidewall.

The sidewall may be textured. DRIE and other anisotropic etching processes generally leave some texture on the sidewall. In some embodiments of the invention, this texture is deliberately exaggerated to modify optical properties of the walls. In an embodiment, roughness features greater than about 80 nm, for example about 100 nm to about 200 nm in size, are provided with a SiC layer which protects against hydrogen erosion but also reflects and scatters radiation that might otherwise be transmitted at grazing incidence.

According to an aspect, a spectral purity filter configured to transmit extreme ultraviolet radiation, the spectral purity filter including a filter part having a plurality of apertures to transmit extreme ultraviolet radiation and to suppress transmission of a second type of radiation, the filter part including a semiconductor material, such as silicon, and a surface layer of hydrogen-resistant material. The thickness of the filter part may be smaller than about 20 μm. The diameter of each aperture may be greater than about 2 μm or in the range of about 2 μm to about 10 μm. The apertures have a period of in the range of about 3 μm to about 6 μm. The filter part may be substantially planar, and the plurality of apertures may extend from a front surface to a rear surface of the filter part to transmit the extreme ultraviolet radiation while suppressing transmission of the second type of radiation. Each aperture may be defined by a textured sidewall having a roughness of at least about 80 nm. The reflective material may extend at least about 1 μm along the sidewalls of the apertures. The layer of hydrogen resistant material may at least in part include SiN SiC and/or SiO₂. The filter may include an integral filter holder.

Another aspect of the invention is to provide a spectral purity filter for extreme ultraviolet radiation, the spectral purity filter comprising a generally planar filter part having a plurality of apertures sized and arrayed so as to transmit extreme ultraviolet radiation while suppressing transmission of a second type of radiation, each aperture being defined by a sidewall extending between front and rear surfaces of the filter part, wherein the sidewall is textured to present non-grazing incidence surfaces.

The reflective surfaces, potentially the whole of the sidewall surface, may have a layer of a material reflective to said first and/or second type of radiation. The filter part may be of semiconductor such as Si, while the reflecting surfaces are for example SiC.

According to an embodiment of the present invention, there is provided a lithographic apparatus that includes a radiation source configured to generate radiation including extreme ultraviolet radiation, an illumination system configured to condition the radiation into a beam of radiation, and a support configured to support a patterning device. The patterning device is configured to pattern the beam of radiation. The apparatus also includes a projection system configured to project a patterned beam of radiation onto a target material, and a spectral purity filter configured to filter the extreme ultraviolet radiation from other radiation. The spectral purity filter may be a spectral purity filter configured to transmit extreme ultraviolet radiation including a filter part having a plurality of apertures to transmit extreme ultraviolet radiation and to suppress transmission of a second type of radiation, the filter part including a semiconductor material and a surface layer of hydrogen-resistant material. Such a spectral purity filter may be a spectral purity filter mentioned above. The spectral purity filter may include a grid-like structure fabricated in a semiconductor material such as silicon, and provided with a surface layer of hydrogen-resistant material over all or a majority of its surface area.

According to an embodiment of the present invention there is provided a method for manufacturing a transmissive spectral purity filter, the method comprising etching a plurality of apertures in a semiconductor substrate using an anisotropic etching process to form a grid-like filter part. The apertures may have a diameter greater than a wavelength of extreme ultraviolet radiation while being smaller than or equal to a wavelength of second radiation to be suppressed. For instance, the diameter may be in a range of about 1.5 μm to about 6 μm or in a range of about 2 μm to about 4 μm. According to the method, a protective layer of hydrogen-resistant material may be provided over all or a majority of the surface area.

The etching may create textured sidewalls that define the apertures. Texture in those sidewalls may be of a dimension exceeding about 80 nm, in order to present non-grazing incidence reflecting surfaces to radiation incident on the side walls. The reflecting surfaces may be provided with a layer of material which is both resistant to hydrogen and reflective to some or all of the second wavelength radiation. SiC is the material which is both reflective and hydrogen-resistant. Optionally, the reflective layer may include molybdenum or ruthenium.

Different materials may be provided to form said hydrogen-resistant layer on different parts of the filter part. A front surface of the part, between the apertures, may for example have a metallic layer (for example Mo) to enhance reflection of the second wavelengths.

Providing the surface layer of hydrogen-resistant material may include: depositing said material directly on the semiconductor material of the filter part; depositing a precursor material and processing the filter part to modify said precursor material into the hydrogen-resistant material; and/or processing the filter part to modify said semiconductor material into the hydrogen-resistant material. The etching process may include alternately exposing the substrate to an SF₆ plasma and a fluor carbon plasma.

The method may include providing a semiconductor substrate having an etch stop layer and using the anisotropic etching process to etch through the semiconductor substrate so that the apertures reach the etch stop layer. The method may further include removing the etch stop layer after having manufactured the apertures in the substrate. The etch stop layer may be provided within the semiconductor substrate, spaced-apart from two outer substrate surfaces. Optionally, the apertures have a diameter in a range of about 100 nm to about 10 μm.

According to an embodiment of the present invention, anisotropic etching of the apertures is performed in a silicon substrate using deep reactive ion etching. The silicon substrate has a thickness of about 10 μm, and the apertures have diameters in the range of about 1.5 μm to about 10 μm, for example about 1.5 μm to about 6 μm or even about 2 μm to about 4 μm.

The etching in some embodiments creates textured sidewalls that run perpendicular to the plane of the filter part and define the apertures. The texturing can be of a dimension exceeding about 50 nm, for example between about 100 nm and about 200 nm, in order to present non-grazing incidence reflecting surfaces to radiation incident on the side walls. The reflecting surfaces may be provided with a layer of material which is both resistant to hydrogen and reflective to some or all of said second wavelength radiation. SiC is one such material.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts schematically a lithographic apparatus according to an embodiment of the invention;

FIG. 2 depicts the layout of a lithographic apparatus according to an embodiment of the present invention;

FIG. 3 is a front view of a spectral purity filter in accordance with an embodiment of the present invention;

FIGS. 4A-4E depicts a schematic overview of an embodiment of a manufacturing process of a spectral purity filter, prior to formation of a hydrogen-resistant layer;

FIG. 5 is a micrographic image of a tilted cross-section of a spectral purity filter at an intermediate stage of manufacture in accordance with an embodiment of the present invention;

FIG. 6 is a more detailed image of the wall between two apertures in the spectral purity filter of FIG. 5;

FIG. 7 is a top view of part of the spectral purity filter in accordance with an embodiment of the present invention;

FIG. 8 is a schematic cross section of a spectral purity filter incorporating a hydrogen protective layer in accordance with an embodiment of the present invention;

FIGS. 9A and 9B illustrate one type of process for the manufacture of a protective layer in accordance with an embodiment of the present invention;

FIGS. 10A to 10C illustrate another type of process for the manufacture of a protective layer in accordance with an embodiment of the present invention;

FIG. 11 is a schematic cross section of a spectral purity filter with enlarged sidewall detail in accordance with an embodiment of the present invention;

FIGS. 12, 13 and 14 are schematic cross sections of spectral purity filters incorporating protective layers and reflective layers in accordance with three different embodiments of the invention.

### DETAILED DESCRIPTION

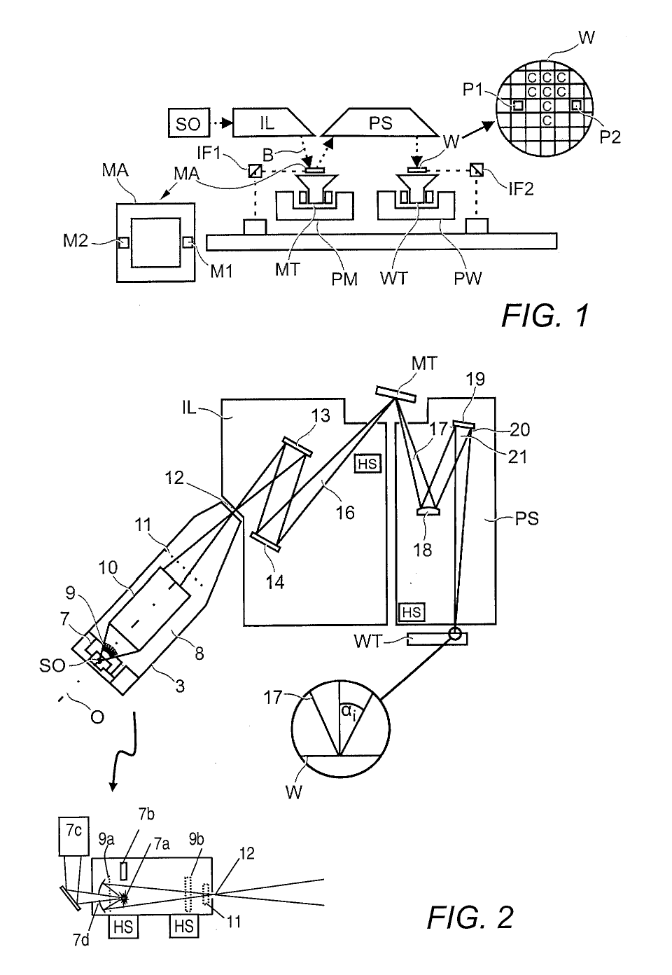

FIG. 1 depicts schematically the main features of a lithographic apparatus. The apparatus includes a radiation source SO and an illumination system (illuminator) IL configured to condition a radiation beam B (e.g. UV radiation or EUV radiation) from the source. A support MT (e.g. a mask table) is configured to support a patterning device MA (e.g. a mask or a reticle) and is connected to a first positioner PM configured to accurately position the patterning device in accordance with certain parameters. A substrate table (e.g. a wafer table) WT is configured to hold a substrate W (e.g. a resist-coated semiconductor wafer) and is connected to a second positioner PW configured to accurately position the substrate in accordance with certain parameters. A projection system PS is configured to project a pattern imparted to the radiation beam B by patterning device MA onto a target portion C (e.g. including one or more dies) of the substrate W.

The illumination system may include various types of optical components, such as refractive, reflective, magnetic, electromagnetic, electrostatic or other types of optical components, or any combination thereof, to direct, shape, or control radiation.

The support MT supports the patterning device. It holds the patterning device in a manner that depends on the orientation of the patterning device, the design of the lithographic apparatus, and other conditions, for example whether or not the patterning device is held in a vacuum environment. The support can use mechanical, vacuum, electrostatic or other clamping techniques to hold the patterning device. The support may be a frame or a table, for example, which may be fixed or movable as required. The support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. Generally, the pattern imparted to the radiation beam will correspond to a particular functional layer in a device being created in the target portion, such as an integrated circuit. It should be noted that the pattern imparted to the radiation beam may not exactly correspond to the desired pattern in the target portion of the substrate, for example if the pattern includes phase-shifting features or so called assist features.

The patterning device may be transmissive or reflective. For practical reasons, current proposals for EUV lithography employ reflective patterning devices, as shown in FIG. 1. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of a vacuum. It may be desired to use a vacuum for EUV or electron beam radiation since other gases may absorb too much radiation or electrons. A vacuum environment may therefore be provided to the whole beam path with the aid of a vacuum wall and vacuum pumps. An example specific to EUV is described below, with reference to FIG. 2.

Any use of the term “projection lens” herein may be considered as synonymous with the more general term “projection system”. For EUV wavelengths, transmissive materials are not readily available. Therefore “lenses” for illumination and projection in an EUV system will generally be of the reflective type, that is to say, curved mirrors.

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located, for example, between the projection system and the substrate during exposure.

Referring to FIG. 1, the illuminator IL receives radiation from radiation source SO. The source and the lithographic apparatus may be separate entities, for example when the source is an excimer laser. In such cases, the source is not considered to form part of the lithographic apparatus and the radiation is passed from the source SO to the illuminator IL with the aid of a beam delivery system (not shown) including, for example, suitable directing mirrors and/or a beam expander. In other cases the source may be an integral part of the lithographic apparatus. The source SO and the illuminator IL, together with the beam delivery system if required, may be referred to as a radiation system.

The illuminator IL may include an adjusting device (adjuster) configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator and a condenser. The illuminator may be used to condition the radiation beam, to have a desired uniformity and intensity distribution in its cross-section.

The radiation beam B is incident on the patterning device MA, which is held on the support MT, and is patterned by the patterning device. After being reflected from the patterning device MA, the radiation beam B passes through the projection system PS, which focuses the beam onto a target portion C of the substrate W. With the aid of the second positioner PW and a position sensor IF2 (e.g. an interferometric device, linear encoder or capacitive sensor), the substrate table WT can be moved accurately, e.g. so as to position different target portions C in the path of the radiation beam B. Similarly, the first positioner PM and another position sensor IF1(which may also be an interferometric device, linear encoder or capacitive sensor) can be used to accurately position the patterning device MA with respect to the path of the radiation beam B, e.g. after mechanical retrieval from a mask library, or during a scan.

In general, movement of the mask support MT may be realized with the aid of a long-stroke module (coarse positioning) and a short-stroke module (fine positioning), which form part of the first positioning device PM. Similarly, movement of the substrate table WT may be realized using a long-stroke module and a short-stroke module, which form part of the second positioning device PW. In the case of a stepper, as opposed to a scanner, the support MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the mask table MT and the substrate table WT are scanned synchronously while a pattern imparted to the radiation beam is projected onto a target portion C (i.e. a single dynamic exposure). The velocity and direction of the substrate table WT relative to the mask table MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, a programmable patterning device MA is kept essentially stationary , and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be referred to as “maskless lithography” that utilizes programmable patterning device, such as a programmable mirror array of a type as referred to above.

Combinations and/or variations on the above described modes of use or entirely different modes of use may also be employed.

FIG. 2 shows a schematic side view of a practical EUV lithographic apparatus. It will be noted that, although the physical arrangement is different to that of the apparatus shown in FIG. 1, the principle of operation is similar. The apparatus includes a source-collector-module or radiation unit 3, an illumination system IL and a projection system PS. Radiation unit 3 is provided with a radiation source 7, SO which may employ a gas or vapor, such as for example Xe gas or a vapor of Li, Gd or Sn in which a very hot discharge plasma is created so as to emit radiation in the EUV range of the electromagnetic radiation spectrum. The discharge plasma is created by causing a partially ionized plasma of an electrical discharge to collapse onto the optical axis O. Partial pressures of, for example, 10 Pa 0.1 m bar of Xe, Li, Gd, Sn vapor or any other suitable gas or vapor may be desired for efficient generation of the radiation. In an embodiment, a Sn source as EUV source is applied.

The main part of FIG. 2 illustrates radiation source 7 in the form of a discharge-produced plasma (DPP). The alternative detail at lower left in the drawing illustrates an alternative form of source, using a laser-produced plasma (LPP). In the LPP type of source, an ignition region 7a is supplied with plasma fuel, for example droplets of molten Sn, from a fuel delivery system 7b. A laser beam generator 7c and associated optical system deliver a beam of radiation to the ignition region. Generator 7c may be a CO₂ laser having an infrared wavelength, for example 10.6 micrometer or 9.4 micrometer. Alternatively, other suitable lasers may be used, for example having respective wavelengths in the range of 1-11 micrometers. Upon interaction with the laser beam, the fuel droplets are transferred into plasma state which may emit, for example, 6.7 nm radiation, or any other EUV radiation selected from the range of 5-20 nm. EUV is the example of concern here, though a different type of radiation may be generated in other applications. The radiation generated in the plasma is gathered by an elliptical or other suitable collector 7d to generate the source radiation beam having intermediate focus 12.

Returning to the main part of FIG. 2, the radiation emitted by radiation source SO is passed from the DPP source chamber 7 into collector chamber 8 via a contaminant trap 9 in the form of a gas barrier or “foil trap”. This will be described further below. collector chamber 8 may include a radiation collector 10 which is , for example, a grazing incidence collector comprising a nested array of so-called grazing incidence reflectors. Radiation collectors suitable for this purpose are known from the prior art. The beam of EUV radiation emanating from the collector 10 will have a certain angular spread, perhaps as much as 10 degrees either side of optical axis O. In the LPP source shown at lower left, a normal incidence collector 7d is provided for collecting the radiation from the source.

Radiation passed by collector 10 transmits through a spectral purity filter 11 according to embodiments of the present invention. It should be noted that in contrast to reflective grating spectral purity filters, the transmissive spectral purity filter 11 does not change the direction of the radiation beam. Embodiments of the filter 11 are described below. The radiation is focused in a virtual source point 12 (i.e. an intermediate focus) from an aperture in the collection chamber 8. From chamber 8, the radiation beam 16 is reflected in illumination system IL via normal incidence reflectors 13, 14 onto a reticle or mask positioned on reticle or mask table MT. A patterned beam 17 is formed which is imaged by projection system PS via reflective elements 18, 19 onto wafer W mounted wafer stage or substrate table WT. More elements than shown may generally be present in the illumination system IL and projection system PS. One of the reflective elements 19 has in front of it an NA disc 20 having an aperture 21 there-through. The size of the aperture 21 determines the angle a, subtended by the patterned radiation beam 17 as it strikes the substrate table WT.

FIG. 2 shows the spectral purity filter 11 positioned closely upstream of the virtual source point 12. In alternative embodiments, not shown, the spectral purity filter 11 may be positioned at the virtual source point 12 or at any point between the collector 10 and the virtual source point 12. The filter can be placed at other locations in the radiation path, for example downstream of the virtual source point 12. Multiple filters can be deployed.

The gas barrier includes a channel structure such as, for instance, described in detail in U.S. Pat. Nos. 6,614,505 and 6,359,969, which are incorporated herein by reference. The purpose of this contaminant trap is to prevent or at least reduce the incidence of fuel material or by-products impinging on the elements of the optical system and degrading their performance over time. These elements include the collector 10, and also the collector. In the case of the LPP source shown in detail at bottom left of FIG. 2, the contaminant trap includes a first trap arrangement 9a which protects the elliptical collector 7d, and optionally a further trap arrangements such as shown at 9b. The gas barrier may act as a physical barrier (by fluid counter-flow), by chemical interaction with contaminants and/or by electrostatic or electromagnetic deflection of charged particles. In practice, a combination of these methods are employed to permit transfer of the radiation into the illumination system, while blocking the plasma material to the greatest extent possible. As explained in the above-mentioned United States patents, hydrogen radicals in particular may be injected for chemically modifying the Sn or other plasma materials.

Hydrogen radicals can also be applied for cleaning of Sn and other which may already be deposited on the optical surfaces. Further, hydrogen gas may be deployed in the vicinity of the wafer support WT, as a buffer against contaminants from the wafer entering the larger vacuum spaces within the system. In a vacuum environment, typical photoresist materials, not to mention components of the supports and positioning systems, tend to release organic and other gaseous materials which could contaminate the optical components over time.

For all these purposes, hydrogen sources HS are shown deployed for the supplying hydrogen gas to each contaminant trap arrangement 9a, 9b, and at ports to the chambers of the illumination system IL and projection system PS. Some sources may supply molecular hydrogen gas (H₂) as a simple buffer while others generate H radicals. The molecular hydrogen which permeates the vacuum environment can become radicalized by radiation, electric discharge and so forth in the environment.

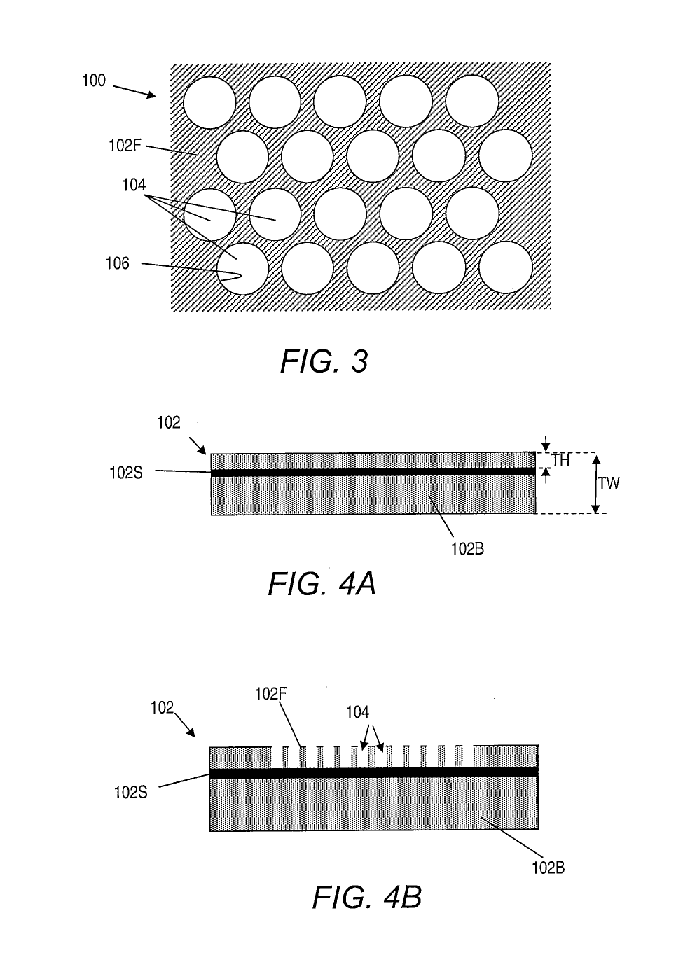

FIG. 3 is a schematic front face view of an embodiment of a spectral purity filter 100, that may for example be applied as an above-mentioned filter 11 of a lithographic apparatus. The present filter 100 is configured to transmit extreme ultraviolet (EUV) radiation. In a further embodiment, the filter 100 substantially blocks a second type of radiation generated by a radiation source, for example infrared (IR) radiation, for example infrared radiation of a wavelength larger than about 1 μm, particularly larger than about 10 μm. Particularly, the EUV radiation to be transmitted and the second type of radiation (to be blocked) can emanate from the same radiation source, for example an LPP source SO of a lithographic apparatus.

The spectral purity filter 100 in the embodiments to be described comprises a substantially planar filter part 102F (for example a filter film or filter layer). The filter part 102F as such can be called a ‘filter substrate’. The filter part 102F has a plurality of (preferably parallel) apertures 104 to transmit the extreme ultraviolet radiation and to suppress transmission of the second type of radiation. The face on which radiation impinges from the source SO will be referred to as the front face, while the face from which radiation exits to the illumination system IL can be referred to as the rear face. As is mentioned above, for example, the EUV radiation can be transmitted by the spectral purity filter without changing the direction of the radiation. In an embodiment, each aperture 104 has been manufactured by an anisotropic etching process, and has parallel sidewalls defining the apertures 104 and extending completely from the front to the rear face.

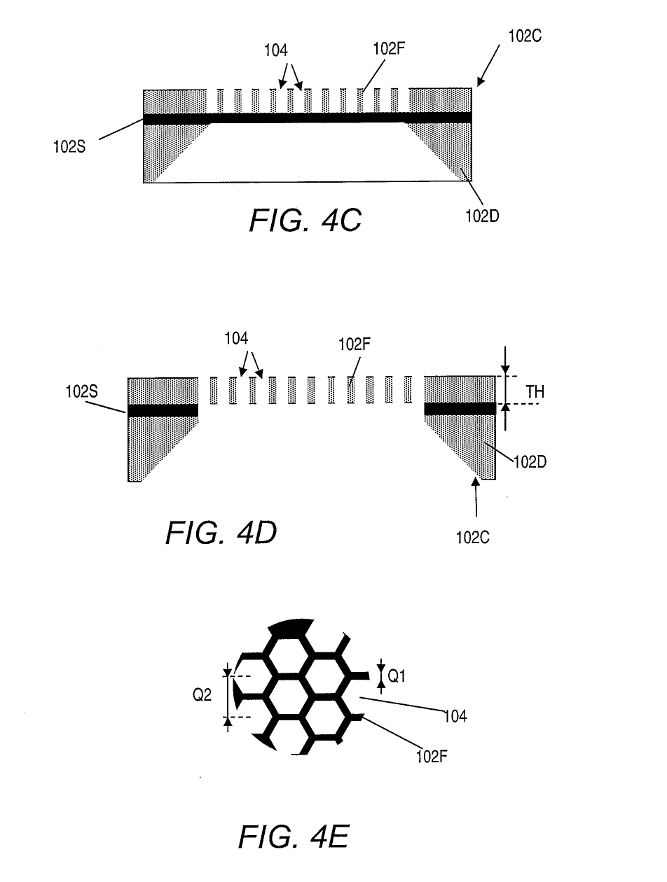

FIGS. 4A-4E show steps in an example process for manufacturing the filter part 102F. This process will be explained briefly below, while further detailed may be found in application no. U.S. Provisional patent application Ser. No. 61/193,769, mentioned above. For example, the filter 100 may include a freestanding thin film of Silicon (Si) 102F and an array of apertures 104 with substantially vertical (i.e. perpendicular to the film surface) sidewalls 106. The diameter of the apertures 104 is desirably larger than about 100 nm and more desirably larger than about 1 μm in order to allow EUV radiation to pass through the spectral purity filter 100 without substantial diffraction. Although the apertures 104 are shown schematically as having a circular cross section (in FIG. 3), other shapes are also possible, and can be preferred. For example, hexagonal apertures (see FIGS. 4E, 5, 6, 8) may be advantageous from the point of view of mechanical stability. A wavelength to be suppressed by the filter 100 can be at least 10x the EUV wavelength to be transmitted. Particularly, the filter 100 is configured to suppress transmission of DUV radiation (having a wavelength in the range of about 100-400 nm), and/or infrared radiation having a wavelength larger than 1 μm (for example in the range of 1-11 microns).

According to an embodiment of the invention, the spectral purity filter 100 may be manufactured by using an anisotropic etching method, of which a suitable example the technique of deep reactive ion etching (DRIE), described briefly below. DRIE is an etching method with highly anisotropic etch rates, which enables the manufacturing of vertical etch profiles in Si using the so-called Bosch process. This is described for example in S. Tachi, K. Tsujimoto, S. Okudaira, Low-temperature reactive ion etching and microwave plasma etching of silicon, Appl. Phys. Lett. 52 (1988), 616. The Bosch process consists of alternately exposing the Si surface to an SF₆ plasma and a fluorocarbon (e.g. C₄F₈) plasma. In the first stage, silicon is etched in a more or less isotropic way, whereas in the second stage, the etched profile is covered by a passivation layer. In the next etch, this passivation layer is opened preferentially at the bottom, mainly by ion bombardment, and etching starts again. By repetition of the etch/passivation cycle, the etch proceeds layer by layer downwards into the silicon surface, without lateral spreading.

An embodiment of the filter manufacturing method comprises (i) applying a hard mask of an aperture pattern on top of a freestanding thin Si film, and (ii) deep reactive ion etching the aperture pattern vertically through the entire Si film. An alternative embodiment of the manufacturing method comprises (i) applying a hard mask of an aperture pattern on a substrate with a Si surface, (ii) deep reactive ion etching the aperture pattern vertically into the Si surface to a desired depth, and (iii) removing the part of the substrate below the etched apertures.

Referring now to FIG. 4A, the manufacturing method begins with a planar substrate 102 of silicon. The thickness TW of the substrate 102 is much greater initially than the thickness TH desired for filter part 102F.

The substrate 102 may comprise a SOI (silicon-on-insulator) wafer, for example a (crystalline) Si wafer with an oxide layer 102S buried at a specific depth, e.g. by oxygen ion implantation. The SOI wafer 102 thus consists of a top Si layer (film) 102F, a SiO₂ intermediate layer 102S, and a bottom Si layer 102B. For example, a thickness TW of the wafer can be smaller than 1 mm, for example 670 microns.

FIG. 4B shows the result of using DRIE, by which the aperture pattern (of hexagonal apertures) is etched in the top Si layer (from a front side) that will provide the filter part 102F of thickness TH. The SiO₂ layer 102S acts as an etch stop.

Subsequently, at least part of the bottom Si layer 102B extending under the aperture pattern 104 is etched away using a KOH etch. Desirably, part of the bottom layer 102B is left standing to provide a respective (lower) section of a filter holder 102C. The result is shown in FIG. 4C. Again, the SiO₂ layer 102S may act as an etch stop.

Finally, the SiO₂ may be removed using a buffered oxide etch, the result being depicted in FIG. 4D. Also in this case, desirably, only part of the etch stop layer 102S is removed, to open up the apertures 104, wherein a remaining part of the bottom layer 102S is left standing to provide a respective section of a filter holder 102C.

As follows from FIGS. 4C-4D, desirably, the filter 100 is provided with a filter holder 102C, external to the filter part 102F having the apertures 104. For example, the filter holder 102C can be configured to surround the filter part 102F. Desirably, the filter holder 102C is substantially thicker than the (in this embodiment central) filter part 102F. For example, a thickness of the holder 102C (measured in a direction parallel to the apertures 104) can be over 20 micron, for example at least 0.1 mm.

The present filter holder 102C is an integral part of the filter 100, substantially made of filter part (semiconductor) material. For example, the filter holder 102C can be a frame 102C surrounding the filter part 102F. In the present example, the filter holder 100C still contains part of the etch stop layer (being ‘buried’ in respective substrate material), and a support part 102D that is substantially thicker than the filter part 102F. In the present example, the filter part 102F and the support layer 102D are made from the same material.

FIG. 4E schematically shows part of the hexagonal apertures 104 in the substrate layer 102F, viewed again from the front face. Arrow Q1 indicates a thickness Q1 of the walls between the filter apertures 104 Arrow Q2 indicates the period of the apertures. The thickness Q1 can be relatively small by application of the present manufacturing method. Also, the (close packed) hexagonal structure of the walls of the filter part 102F provides a very durable and open configuration.

Advantageously, EUV radiation is directly transmitted through the apertures 104, preferably utilizing a relatively thin filter 100, in order to keep the aspect ratio of the apertures low enough to allow EUV transmission with a significant angular spread. Thickness TH of the filter part 102F (i.e. the length of each of the apertures 104) is for example smaller than about 20 μm, for example in the range of about 2 μm to about 10 μm, for example the range of about 5 μm to about 10 μm. Also, according to a further embodiment, each of the apertures 104 may have a diameter in the range of about 100 nm to about 10 μm. Desirably, the apertures 104 each have diameter in the range of about 1.5 μm to about 6 μm, for example the range of about 2 μm to about 4 μm.

Referring to the front detail view shown in FIG. 4E, thickness Q1 of the walls between the filter apertures 104 may be smaller than about 1 μm, for example in the range of about 0.4 μm to about 0.6 μm, particularly about 0.5 μm. The apertures of the EUV transmissive filter 100 may have a period Q2 (indicated in FIG. 4E) of in the range of about 3 μm to about 6 μm, particularly about 3 μm to about 4 μm, for example about 4 μm. Consequently, the apertures may provide an open area of about 70-80% of a total filter front surface.

Advantageously, the filter 100 is configured to provide at most 5% infrared light (IR) transmission. Also, advantageously, the filter 100 is configured to transmit at least 60% of incoming EUV radiation at a normal incidence. Besides, particularly, the filter 100 can provide at least about 40% of transmission of EUV radiation having an angle of incidence (with respect of a normal direction) of about 10°.

The semiconductor filter part 102F produced by the process described above can perform as a spectral purity filter without modification. In a practical embodiment, however, modifications such as those to be described below can be implemented, however, to improve filter performance and longevity. In a particular embodiment, according to the present invention, an additional layer or layers are provided to protect the semiconductor material from attack by the hydrogen or other radicals in the atmosphere. Embodiments include the filter part 102F being selected from one or more of: a semiconductor part, a crystalline semiconductor part, a doped semiconductor part, a coated semiconductor part, and an at least partly modified semiconductor part. Filter part 102F may contain at least one semiconductor material selected from silicon, germanium, diamond, gallium arsenide, zinc selenide, and zinc sulfide.

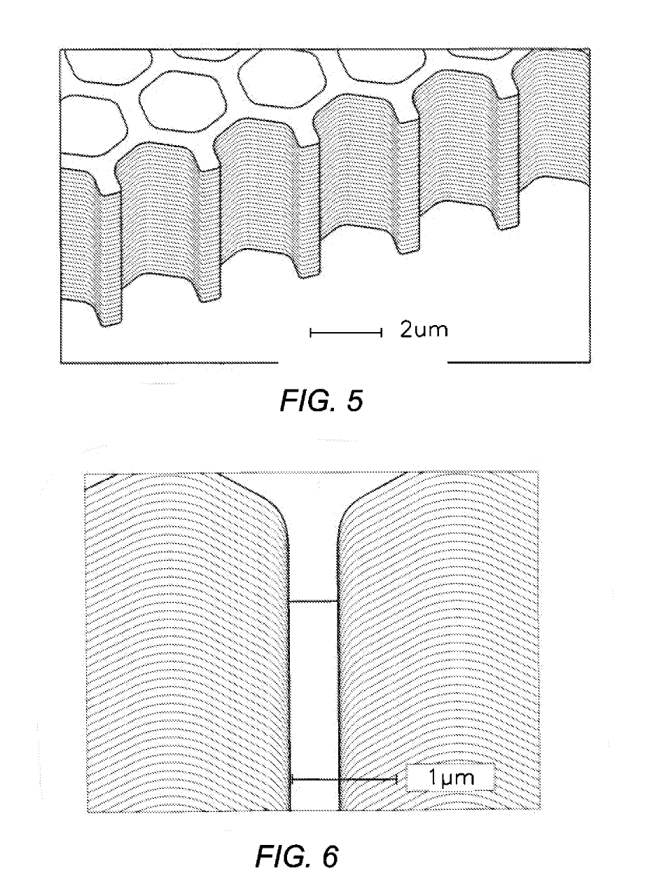

FIGS. 5 and 6 illustrate examples of spectral purity filters that have been manufactured in accordance with the process described above. FIG. 5 is an image of tilted cross sectional view of a spectral purity filter having apertures with a period of about 3 μm. The depth of the apertures (corrected for the viewing angle) is about 10.8 μm.

FIG. 6 is a close-up detail in a tilted cross section of a wall between two apertures. A top layer seen in FIG. 6 is an SiO₂ hard mask used for the Bosch process and has a thickness of about 400 nm when corrected for the viewing angle. As best seen in FIG. 6, the walls are textured, particularly ribbed or scalloped, and so have a periodic thickness variation along the surface of the wall. This scalloping effect arises from the cycles of etching and passivation in the described deep reactive ion etching (DRIE) process. Conventionally, the texture is minimized to the extent compatible with process practicalities and throughput. The inventors note, however, that the etching speed and/or duration of these cycles can be modified deliberately to provide an amplified texture, which may be applied to modify optical properties of the sidewall, as described below.

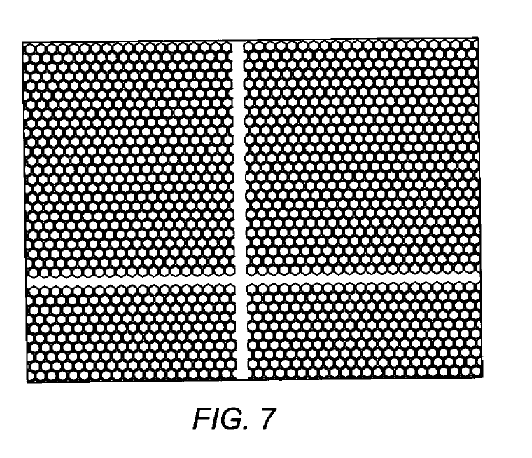

FIG. 7 is a top view of a freestanding spectral purity filter 100 in accordance with an embodiment of the present invention. Several grid SPF types can be distinguished based on different mechanisms for suppression of unwanted 10.6 μm radiation. The Si grid in accordance with embodiment of this invention may be modified according to the specifications of these grid types.

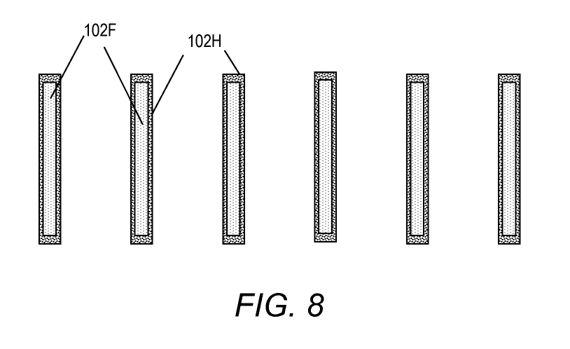

FIG. 8 shows a modified spectral purity filter part 102F in which a protective layer 102H is formed over the entire exposed surface of the grid material. Protective layer 102H is of a material more resistant to attack by hydrogen radicals than the Si or other grid material.

Example materials for protective layer 102H include: Si₃N₄ and/or SiN (silicon nitride), SiO₂ (silicon dioxide), and SiC (silicon carbide).

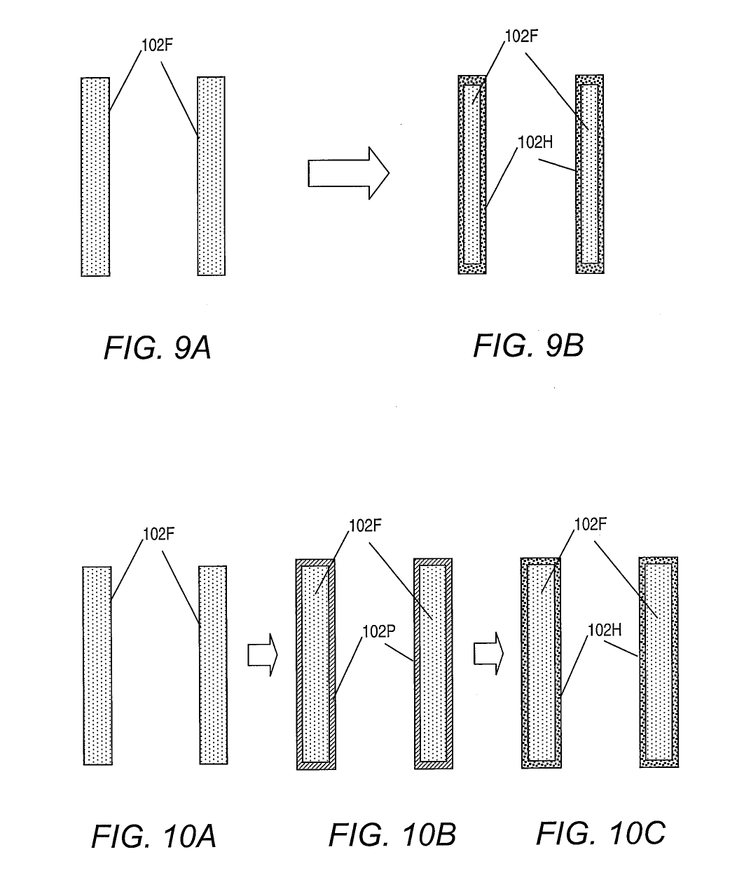

Other materials may be considered for other semiconductor substrates and other types of substrate material. Each of these materials has potential advantages and disadvantages in terms of optical properties, ease of manufacturing, compatibility with substrate material and other layers (for example reflective layers), as discussed below. Three broad classes of process can be envisaged for the provision of the protective layer. In a first type of process, the material of the protective layer 102H is simply deposited on the grid material of filter part 102F. FIGS. 9A and 9B illustrate a second type of process in which the protective material is formed by modifying a surface layer of the substrate material, such as silicon, in the filter part 102F. FIGS. 10A, 10B, 10C illustrate a third and fourth type of process in which the protective layer 102H is applied by a two step process. In a first step, a precursor material 102P is applied to the filter part 102F. In a second step, the precursor material is modified by interaction with the environment, or modifies the substrate material, to form the protective material 102H.

These may be used alone or in combination with one another. Different materials and processes can in principle be used at different parts of the structure. Example processes are mentioned below for producing example protective materials, but these are not to be taken as the only processes applicable to produce a given material. The choice of process will also determine whether, for example, a uniform coating is achieved over all parts of the substrate, or whether certain faces are coated preferentially, and others only weakly if at all.

For the example of Si₃N₄ and/or SiN layer 102H on a silicon substrate, the nitride material can be produced by the second type of method. The filter part 102F, already made into its grid form, is exposed to a flow of nitrogen radicals or ions. This may be a cold nitrogen plasma, for example. Interaction of these radicals with the silicon will form a thin film of Si₃N₄ on the surface, as shown in FIG. 9B. Even a very thin layer protects against hydrogen attack. The thickness of the layer 102H may be for example less than about 50 nm, in particular in the range of about 5 nm to about 30 nm, or about 20 nm.

For the example of SiC layer 102H on a silicon substrate, again the carbide material can be produced by modifying the surface layer of a silicon substrate. Exposing the substrate to methane (CH4) in a near-vacuum and heating[is one method. Again, with SiC a thin layer can protect against hydrogen attack: 1-50 nm.

For producing SiO₂ it is well-known to heat the silicon substrate in an oxygen plasma or simply in O₂ atmosphere. Again, with SiO2 a thin layer can protect against hydrogen attack: 1-50 nm, say 5-20 nm.

Each of the protective materials has its own optical properties. Silicon carbide SiC, in particular, has a relatively high reflectance in the unwanted IR wavelengths. Where optical properties are being exploited, the layer thickness may be dictated by the desired optical properties to be thicker than is desired simply for hydrogen shielding. A thin coating is beneficial for management of thermal stresses in operation, especially where the material has very different thermal expansion from the substrate. Too thick a coating may delaminate due to difference in the thermal expansion coefficients.

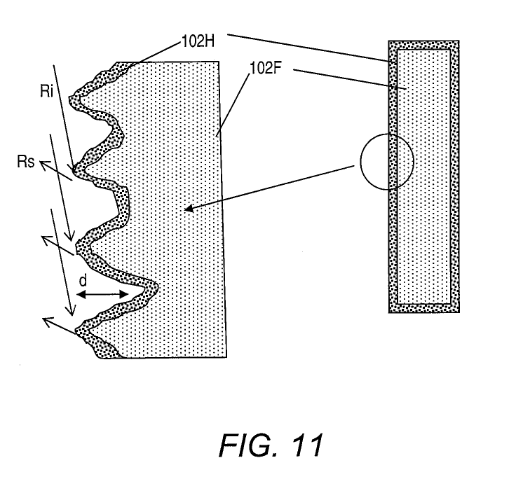

FIG. 11 illustrates a modified filter part 102F in which a protective layer 102H is also reflective of unwanted radiation, and in which a sidewall of the aperture 104 is provided with enhanced roughness. With a smooth sidewall, having for example a few nm or a few tens of nm deviation, the longer wavelength radiation Ri which enters the aperture will impinge on the sidewall with grazing incidence, and will not be greatly scattered. Applying an enhanced roughness with a typical dimension d greater than about 50 nm, for example about 100 nm or even about 200 nm, larger scattering surfaces are presented to the radiation Ri at non-grazing incidence, promoting greater scattering Rs. This can enhance the attenuation of such wavelengths in the filter. In the case of scalloped walls such as produced by DRIE, the dimension d may be the depth of the scallop as indicated. In a more random form of roughness, d would express for example an average diameter of grains forming the surface, while the grain size might vary by +/−50%.

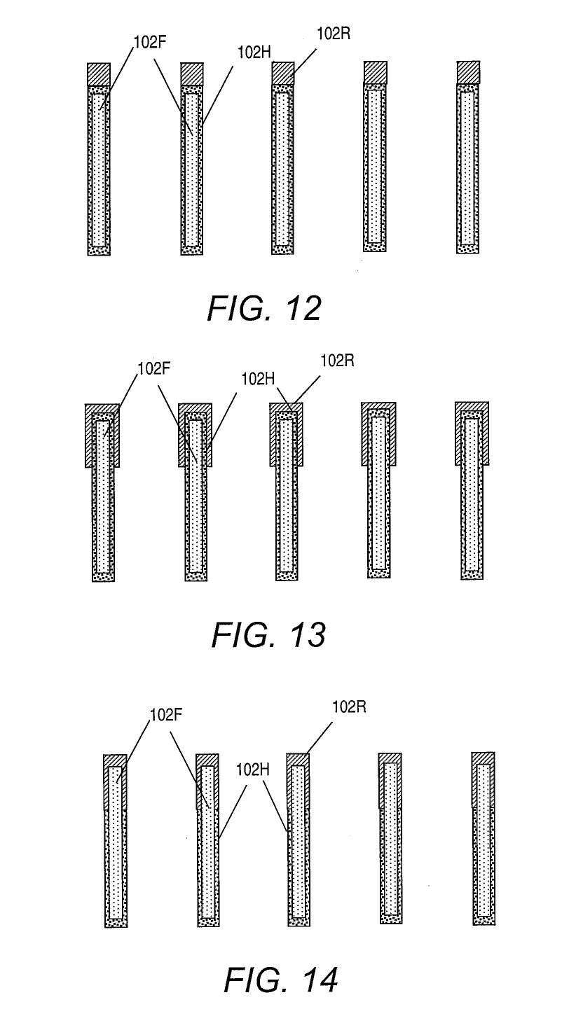

FIGS. 12 to 14 illustrate schematically further modifications in which the Si grid is coated with a thin reflective layer, preferably a metal, for example molybdenum. Depending on the deposition method and conditions two types of deposition geometries can occur. FIG. 12 shows a cross section where metal covers only the top part of the silicon grid, while FIGS. 13 and 14 shows a cross sections where the metal covers an upper part of the sides of the sidewalls as well.

Simulation results obtained using the GSolver simulation package for a silicon filter grid without protective layer 102H are given in co-pending patent application U.S. Provisional patent application Ser. No. 61/193,769, mentioned above. These results suggest that, where Mo is deposited only on the top surface of a silicon grid, a thick metal coating of about 2 μm may be desirable to achieve the desired suppression of IR wavelengths. The desired metal thickness can be reduced by using a smaller period of the grid, but in that case the transmission of the wanted EUV radiation is also likely to be reduced. When the metal coating covers both the top surface and the sidewalls of the silicon grid, as shown in FIG. 12 or 13, however, the situation changes dramatically. In that case, IR transmission drops to nearly zero already for a coating of only a few nanometers thickness. At such small thickness, most power is absorbed in the grid. In order to make the grid substantially reflective, e.g. with 95% reflectivity, a coating of only about 30 nm, or less than about 50 nm, is used. A thin coating is also beneficial for management of thermal stresses in operation.

One method to apply a reflective coating on the filter (for example Silicon) grid with a minimal loss of EUV transmittance is by atomic layer deposition (ALD). In this way, a uniform coating thickness of a three-dimensional coating structure 102R can be achieved. Since the thickness of the coating is uniform, a desired infrared reflectivity can be achieved with a minimal loss of EUV transmittance due to excess coating thickness. Particularly, by application of ALD, excess coating thicknesses at the top of the grid can be avoided, whilst retaining sufficient coating thickness down the sidewalls 106 of the grid 102F. ALD uses alternating steps of a self-limiting surface reaction to deposit atomic layers one by one. The material to be deposited is provided through a precursor. ALD methods are known for several metals, for example, Mo, Ti, Ru, Pd, Ir, Pt, Rh, Co, Cu, Fe and Ni. A preferred embodiment may use a reflective coating 102F consisting of ruthenium (Ru) instead of Mo. Often it will be the case that Ru is already present in a system that is to utilize the filter. For example a lithographic apparatus may have an EUV source-collector module that comprises Ru. Alternatively, the reflective coating 102R may not a metal but another material that is reflective for the unwanted radiation, for example TiN or RuOx, or a conductor material.

Instead of ALD, galvanic growth (electrodeposition) may be used to deposit the reflective coating 102R. Metals can also be deposited on a Si grid, for example by evaporation or sputter deposition.

It may not be practical or desirable to apply a reflective coating that fully covers the sidewalls of a 10 μm thick grid. For example, it may be advantageous to leave the back side of the grid 102F uncoated to increase the emissivity and thus enhance radiative cooling of the grid. Therefore, in an embodiment, the coating is applied only partly down the sidewalls. For example, when the reflective coating is applied on top of the grid and down the first 2 μm along the sidewalls of the grid, the optical behavior is essentially the same as when the whole sidewall is coated. Accordingly, unless additional protective measures are taken, the underlying grid material such as silicon or other semiconductor will be exposed to the hydrogen radicals or other components of the atmosphere inside the vacuum system which may attack the grid material, and simultaneously transfer particles of it to contaminate the optical surfaces and other parts of the system.

FIG. 13 illustrates an embodiment in which the reflective metal layer 102R is applied after creation of a hydrogen resistant protective layer 102P. Alternatively, the metal layer could be beneath the protective layer. The optical properties may be affected by the protective layer, or they may not if it is very thin. Where the protective layer is beneath the metal layer, the protective layers may act also as a barrier to reactions between the metal and the silicon or other substrate 102F. Particularly if the filter part is expected to get hot in operation, mixing and chemical combination would gradually occur, degrading the IR reflective performance of the metal layer, and leading to yet further heating as a result).

FIG. 14 illustrates an embodiment in which the reflective layer 102R and the protective layer 102H cover different parts of the structure. The different layers in this case may be applied by separate processes. The different parts may even be obtained by different treatment of a common precursor material.

Besides metal, it is mentioned above that SiC is reflective to IR. SiC can thus be used as the reflective coating on front face and sidewalls of the filter, or a combination of metal on the front face and SiC on the side may be used for ease of manufacture. Reflectance of the front surface may be greatly enhanced if the reflective coating extends a reasonable distance down the sidewalls.

Note that at grazing incidence, SiC and other materials may be reflective at additional wavelengths, including the ‘wanted’ EUV wavelengths. Where it is desired that the filter should not contribute to the spreading of the EUV radiation beam, grazing incidence reflection off the sidewalls may be undesirable. The provision of texture can be advantageous to avoid grazing incidence reflections, whether the surfaces of the sidewall are coated with materials reflective to EUV or not.

In some SPFs, the 10.6 μm radiation or other unwanted radiation may be absorbed in the grid material. Such a grid can be realized with embodiment of the present invention by using doped Si. A typical embodiment according to this aspect of the invention comprises a Si grid with a doping concentration in excess of 10¹⁸ atoms/cm³. As explained in co-pending application U.S. Provisional patent application Ser. No. 61/193,769, mentioned above, the refractive index of Si can be substantially changed by doping it with n-type impurities such as P or As. High values of doping can render the grid material substantially absorbing rather than transparent.

For example, a grid made of pure silicon shows oscillations in the transmission as a function of its thickness, due to interference in the layer. While transmission can be modified also by controlling the thickness of the grid material to exploit interference effects, the risk is that that overall the transmission remains high. A grid with the same dimensions made of n-type doped Si shows a continuous decrease of IR transmission as a function of the grid thickness. For example, at a grid thickness (depth) of 9 μm, about 4% of the incident infrared radiation is transmitted, about 12% is reflected, and the remainder (about 84%) is absorbed. Thus, the grid is substantially absorptive. Similar behavior is expected for p-type doped Si.

A manufacturing method for a doped Si grid may be the same as for a pure Si grid as described earlier, with the starting material comprising doped Si rather than pure Si. It is not expected that the doping will affect the DRIE process significantly. In alternative manufacturing methods, the doping may be introduced after manufacturing of the grid, for example by ion implantation or thermal diffusion.

An embodiment can include creating a microlens array (for example as part of the filter). For example, microlens array SPF may be created by laterally varying the doping concentration in the Si grid. This produces so-called graded index (GRIN) lenses due to the dependence of the refractive index on doping concentration as described above. The desired variation in doping concentration may be accomplished for example by using a focused ion beam, or by using uniform ion implantation in combination with a suitable mask. Another way to create a microlens array SPF is to vary the thickness TH of the Si grid 102F laterally. This may be done before or after manufacturing of the Si grid, e.g. by micromachining or lithography. Alternatively, one of the etch processes in the manufacturing of the grid may be modified such that the desired variation in thickness is obtained during etching.

It will be understood that the apparatus of FIGS. 1 and 2 incorporating the spectral purity filter with hydrogen resistance may be used in a lithographic manufacturing process. Such lithographic apparatus may be used in the manufacture of ICs, integrated optical systems, guidance and detection patterns for magnetic domain memories, flat-panel displays, liquid crystal displays (LCDs), thin-film magnetic heads, etc.. It should be appreciated that, in the context of such alternative applications, any use of the term “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The descriptions above are intended to be illustrative, not limiting. Thus, it should be appreciated that modifications may be made to the present invention as described without departing from the scope of the claims set out below.

It will be appreciated that embodiments of the invention may be used for any type of EUV source, including but not limited to a discharge produced plasma source (DPP source), or a laser produced plasma source (LPP source). However, an embodiment of the invention may be particularly suited to suppress radiation from a laser source, which typically forms part of a laser produced plasma source. This is because such a plasma source often outputs secondary radiation arising from the laser.

The spectral purity filter may be located practically anywhere in the radiation path. In an embodiment, the spectral purity filter is located in a region that receives EUV-containing radiation from the EUV radiation source and delivers the EUV radiation to a suitable downstream EUV radiation optical system, wherein the radiation from the EUV radiation source is arranged to pass through the spectral purity filter prior to entering the optical system. In an embodiment, the spectral purity filter is in the EUV radiation source. In an embodiment, the spectral purity filter is in the EUV lithographic apparatus, such as in the illumination system or in the projection system. In an embodiment, the spectral purity filter is located in a radiation path after the plasma but before the collector.

While specific embodiments of the present invention have been described above, it should be appreciated that the present invention may be practiced otherwise than as described.

1. A spectral purity filter configured to transmit extreme ultraviolet radiation, the spectral purity filter comprising a filter part having a plurality of apertures to transmit extreme ultraviolet radiation and to suppress transmission of a second type of radiation, the filter part comprising a semiconductor material and a surface layer of hydrogen-resistant material.

2. The filter according to claim 1, further comprising a layer of reflective material on a front surface that is configured to be reflective to said second type of radiation.

3. The filter according to claim 2, wherein said reflective material forms part of said hydrogen-resistant layer, while another material forms another part of said hydrogen-resistant layer.

4. The filter according to claim 1, wherein said layer of hydrogen resistant material at least partly comprises one material selected from the group consisting of: silicon nitride Si₃N₄, silicon nitride SiN, silicon dioxide SiO₂, and silicon carbide SiC.

5. The filter according to claim 1, wherein different hydrogen-resistant materials are provided to form a protective layer on different parts of the filter part.

6. The apparatus according to claim 1, wherein a front surface of the part, between the apertures, is provided with a metallic layer to enhance reflection of the second type of radiation.

7. A lithographic apparatus comprising:
a radiation source configured to generate radiation comprising extreme ultraviolet radiation;
an illumination system configured to condition the radiation into a beam of radiation;
a support configured to support a patterning device, the patterning device being configured to pattern the beam of radiation;
a projection system configured to project a patterned beam of radiation onto a target material; and
a spectral purity filter configured to transmit extreme ultraviolet radiation, the spectral purity filter comprising a filter part having a plurality of apertures to transmit extreme ultraviolet radiation and to suppress transmission of a second type of radiation, the filter part comprising a semiconductor material and a surface layer of hydrogen-resistant material.

8. An apparatus according to claim 7, wherein said radiation source comprises a fuel delivery system and laser radiation source, the laser radiation source being arranged to deliver radiation at infrared wavelength onto a target comprising plasma fuel material delivered by said fuel delivery system for the generation of said extreme ultraviolet radiation, the radiation source thereby emitting a mixture of extreme ultraviolet and infrared radiation toward said spectral purity filter.

9. An apparatus according to claim 8, wherein a source of hydrogen radicals is arranged to release hydrogen radicals in the vicinity of said radiation source for control of contamination originating in said plasma fuel material.

10. A method for manufacturing a transmissive spectral purity filter, configured to transmit extreme ultraviolet radiation, the method comprising:
etching a plurality of apertures in a semiconductor substrate using an anisotropic etching process to form a grid-like filter part, said apertures having a diameter greater than a wavelength of said extreme ultraviolet radiation while being smaller than or equal to a wavelength of second radiation to be suppressed; and
subsequently providing a protective layer of hydrogen-resistant material over substantially all exposed surfaces of said semiconductor material.

11. The method according to claim 10, further comprising depositing a metal or reflective layer on top of the substrate.

12. The method according to claim 11, further comprising depositing the metal or other reflective layer on at least a part of each sidewall.

13. The method according to claim 11, wherein said hydrogen resistant material is formed by modifying the semiconductor substrate of the filter part.

14. The method filter according to claim 13, wherein said layer of hydrogen resistant material at least partly comprises one material selected from the group consisting of: silicon nitride SiN, silicon nitride Si₃N₄, silicon dioxide SiO₂, and silicon carbide SiC.

15. A spectral purity filter for extreme ultraviolet radiation, the spectral purity filter comprising a generally planar filter part having a plurality of apertures sized and arrayed so as to transmit extreme ultraviolet radiation while suppressing transmission of a second type of radiation, each aperture being defined by a sidewall extending between front and rear surfaces of the filter part, wherein the sidewall is textured to present non-grazing incidence surfaces.
